(19) United States
(12) Patent Application Publication
(10) Pub. No.: US 2019/0350078 A1
(43) Pub. Date: Nov. 14, 2019

(54) METAL-CERAMIC BONDED SUBSTRATE, AND MANUFACTURING METHOD THEREOF

(71) Applicant: Mitsubishi Electric Corporation, Chiyoda-ku, Tokyo (JP)

(72) Inventors: Yuki WAKABAYASHI, Tokyo (JP); Daisuke OYA, Tokyo (JP); Keisuke TANAKA, Tokyo (JP)

(73) Assignee: Mitsubishi Electric Corporation, Chiyoda-ku, Tokyo (JP)

(21) Appl. No.: 16/475,721

(22) PCT Filed: Jan. 10, 2018
(86) PCT No.: PCT/JP2018/000245

§ 371 Date: Jul. 3, 2019

(30) Foreign Application Priority Data
Jan. 13, 2017 (JP) 2017-003816

(51) Int. Cl. H05K 1/05; H05K 1/02; H05K 3/44; B22D 19/02; C04B 37/02

(52) U.S. Cl. CPC H05K 1/053; H05K 1/0203; C04B 2237/86; B22D 19/02; C04B 37/021; H05K 3/44

(57) ABSTRACT

A metal-ceramic bonded substrate is such that a heat dissipating face is formed in a spherical protruding form, because of which contact pressure with a thermally conductive grease when attaching a heat dissipating fin to the heat dissipating face is high, and high heat dissipation can be secured. Also, by an overflow portion communicating with a metal base portion formation portion being provided farther to an outer side than an external form of the metal-ceramic bonded substrate in an interior of a casting mold, an overflow portion residue is restricted by the casting mold when causing molten metal to solidify and cool, because of which warping deformation occurring because of a difference between linear expansion coefficients of a metal material and a ceramic material can be restricted, and a casting defect such as a running defect in a molten metal flowing process, cold shut, a ripple mark, can be restricted.

### TECHNICAL FIELD

The present invention relates to a metal-ceramic bonded substrate manufactured by cooling and hardening molten metal brought into contact with a ceramic substrate, and to a manufacturing method thereof.

### BACKGROUND ART

A metal-ceramic bonded substrate used in a power module for controlling a large current of an electric vehicle, an electric train, a machine tool, or the like, is such that a circuit pattern metal plate and a metal base plate are bonded one to each face of a circuit insulating ceramic substrate. A semiconductor chip is mounted by soldering to the circuit pattern metal plate, and a metal heat dissipating fin or a cooling jacket is attached by screwing or the like to a heat dissipating face of the metal base plate across a thermally conductive grease.

As the heretofore described kind of metal-ceramic bonded substrate is such that metal plates of differing thicknesses, that is, a circuit pattern metal plate and a metal base plate, are bonded one to either side of a ceramic substrate, a large warping is liable to occur after bonding. When a metal-ceramic bonded substrate in which warping deformation has occurred is attached to a heat dissipating fin or a cooling jacket, there is a problem in that heat dissipation decreases due to a clearance forming, and reliability with respect to thermal shock resistance or the like expected of a large current control substrate cannot be satisfied.

In order to resolve this kind of problem, a metal-ceramic bonded substrate wherein at least one reinforcement member is bonded to a metal base plate and one portion of the reinforcement member is exposed outside the metal base plate, and a manufacturing method thereof, are disclosed in, for example, Patent Document 1. In this existing example, warping of the metal-ceramic bonded substrate is restricted by supporting one portion of the reinforcement member with a casting mold when bonding the metal-ceramic bonded substrate.

### CITATION LIST

### Patent Literature

Patent Document 1: JP-A-2011-77389

### SUMMARY OF INVENTION

### Technical Problem

A ceramic plate member of alumina, aluminum nitride, silicon nitride, or the like, is used as a reinforcement member in a metal-ceramic bonded substrate, but as there is a difference between linear expansion coefficients of a ceramic and a metal, the ceramic plate member may become considerably deformed due to solidification contraction when metal in a molten state is brought into contact with the ceramic plate member, cooled, and hardened. In this case, a heat dissipating face of the metal-ceramic bonded substrate may deform into a convex form or a concave form depending on a flatness of the reinforcement ceramic plate member.

When the heat dissipating face of the metal-ceramic bonded substrate deforms into a concave form, heat dissipation decreases noticeably because contact pressure with a thermally conductive grease decreases. Because of this, there is a problem in that a secondary process such as a cutting process that improves a flatness of the heat dissipating face is needed in order to secure heat dissipation, and a manufacturing cost rises.

A method whereby one portion of a reinforcement ceramic plate member exposed outside a metal base plate is supported by a casting mold, as in Patent Document 1, is such that the metal base plate becomes locally thin due to external dimensions of the reinforcement ceramic plate member and the metal-ceramic bonded substrate, a method of holding the reinforcement ceramic plate member, or the like, and there is a problem in that a casting defect, such as a running defect in a molten metal flowing process or surface cracking in a solidification and cooling process, occurs.

Also, a screw fastening hole for attaching the metal-ceramic bonded substrate to a heat dissipating fin or a cooling jacket is formed by a machining process or a pressing process in a peripheral edge portion of the metal-ceramic bonded substrate, but when a distance between an outer periphery of the metal-ceramic bonded substrate and the fastening hole is small, there is a problem in that an external form of the metal-ceramic bonded substrate becomes deformed when processing the fastening hole, and a required external form accuracy is not satisfied.

The invention, having been contrived in order to resolve the heretofore described kinds of problem, has an object of providing a metal-ceramic bonded substrate such that warping deformation is restricted, heat dissipation and external form accuracy are high, and furthermore, a casting defect such as a running defect is restricted, and a manufacturing method thereof.

### Solution to Problem

A metal-ceramic bonded substrate according to the invention includes a circuit insulating ceramic substrate such that a circuit pattern metal plate is bonded to one face and a metal base portion is bonded to another face, and a reinforcement ceramic plate member disposed opposing the circuit insulating ceramic substrate in an interior of the metal base portion, wherein the metal base portion is such that a heat dissipating face, which is a face on a side opposite to that of a face bonded to the circuit insulating ceramic substrate, is of a spherical protruding form.

Also, a metal-ceramic bonded substrate manufacturing method according to the invention is a method of manufacturing a metal-ceramic bonded substrate including a circuit insulating ceramic substrate such that a circuit pattern metal plate is bonded to one face and a metal base portion is bonded to another face, and a reinforcement ceramic plate member disposed opposing the circuit insulating ceramic substrate in an interior of the metal base portion, wherein a heat dissipating face, which is a face of the metal base portion on a side opposite to that of a face bonded to the circuit insulating ceramic substrate, is of a spherical protruding form, wherein a casting mold such that the circuit insulating ceramic substrate and the reinforcement ceramic plate member are set opposing in an interior, the casting mold has an overflow portion communicating with a space for forming the metal base portion farther to an outer side than the space in a horizontal direction, and a face opposing the reinforcement ceramic plate member is cut out into a spherical depressed form, is prepared, molten metal heated to a predetermined temperature is poured into the interior of the casting mold, the molten metal is caused to harden by cooling the casting mold, and the metal-ceramic bonded substrate is removed from the casting mold, after which an overflow portion residue formed integrally with the metal base portion is cut off.

### Advantageous Effects of Invention

According to the metal-ceramic bonded substrate according to the invention, a heat dissipating face of a metal base portion is of a spherical protruding form, because of which, when a heat dissipating fin or a cooling jacket is attached to the heat dissipating face across a thermally conductive grease, high heat dissipation can be secured because contact pressure with the thermally conductive grease is high, and contact is good.

Also, according to the metal-ceramic bonded substrate manufacturing method according to the invention, a metal-ceramic bonded substrate with high heat dissipation wherein a heat dissipating face of a metal base portion is formed by transfer in a spherical protruding form can easily be manufactured by using a casting mold wherein a face opposing a reinforcement ceramic plate member is cut out into a spherical depressed form. Also, an overflow portion residue formed in an overflow portion when causing molten metal to solidify and cool is restricted by the casting mold, because of which warping deformation occurring because of a difference between linear expansion coefficients of a metal material and a ceramic material can be restricted. Also, a casting defect such as a running defect in a molten metal flowing process or surface cracking in a solidification and cooling process can be restricted by the overflow portion being provided neighboring a place in which a channel of the molten metal in an interior of the casting mold is narrow. Furthermore, by a metal-ceramic bonded substrate removed from the casting mold having the overflow portion residue, deformation of an external form of the metal-ceramic bonded substrate caused by a subsequent pressing process can be restricted. For these reasons, according to the invention, a metal-ceramic bonded substrate such that warping deformation is restricted, heat dissipation and external form accuracy are high, and furthermore, a casting defect such as a running defect is restricted, is obtained.

Other objects, characteristics, aspects, and advantages of the invention will become more apparent from the following detailed description of the invention, with reference to the drawings.

### BRIEF DESCRIPTION OF DRAWINGS

FIG. 1 is a plan view showing a metal-ceramic bonded substrate according to a first embodiment of the invention.

FIG. 2 is a sectional view showing the metal-ceramic bonded substrate according to the first embodiment of the invention.

FIG. 3 is a sectional view showing a casting mold used in manufacture of the metal-ceramic bonded substrate according to the first embodiment of the invention.

FIG. 4A and FIG. 4B are a plan view and a sectional view showing a metal-ceramic bonded substrate manufacturing method according to the first embodiment of the invention.

FIG. 5A and FIG. 5B are sectional views showing the metal-ceramic bonded substrate manufacturing method according to the first embodiment of the invention.

FIG. 6 is a sectional view showing a modified example of the metal-ceramic bonded substrate according to the first embodiment of the invention.

FIGS. 7 A and FIG. 7B are a plan view and a sectional view showing a metal-ceramic bonded substrate manufacturing method according to a second embodiment of the invention.

FIG. 8 is a plan view showing the metal-ceramic bonded substrate manufacturing method according to the second embodiment of the invention.

FIG. 9 is a plan view showing the metal-ceramic bonded substrate manufacturing method according to the second embodiment of the invention.

FIG. 10 is a sectional view showing the metal-ceramic bonded substrate manufacturing method according to the second embodiment of the invention.

### DESCRIPTION OF EMBODIMENTS

### First Embodiment

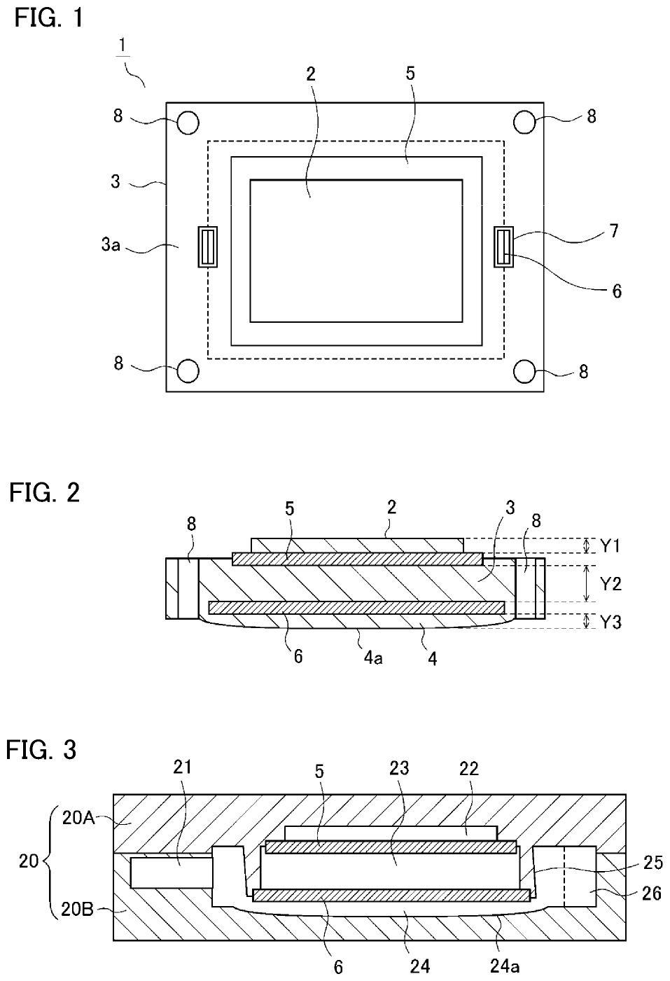

Hereafter, a metal-ceramic bonded substrate according to a first embodiment of the invention, and a manufacturing method thereof, will be described based on the drawings. FIG. 1 and FIG. 2 are a plan view and a sectional view showing the metal-ceramic bonded substrate according to the first embodiment, and FIG. 3 is a sectional view showing a casting mold used in manufacture of the metal-ceramic bonded substrate according to the first embodiment. In all the drawings, identical reference signs are allotted to identical or corresponding portions.

A metal-ceramic bonded substrate 1 according to the first embodiment includes a circuit pattern metal plate 2, a metal base portion 3, a circuit insulating ceramic substrate 5, and a reinforcement ceramic plate member 6.

As shown in FIG. 2, the circuit pattern metal plate 2 is bonded to one face of the circuit insulating ceramic substrate 5, and the metal base portion 3, whose external dimensions and thickness dimension are greater than those of the circuit pattern metal plate 2, is bonded to another face. The circuit pattern metal plate 2 is a part mounting face of the metal-ceramic bonded substrate 1, and a semiconductor chip and the like are mounted on the circuit pattern metal plate 2.

The reinforcement ceramic plate member 6 is disposed opposing the circuit insulating ceramic substrate 5 in an interior of the metal base portion 3. The metal base portion 3 is such that a heat dissipating face 4a, which is a face on a side opposite to that of a face bonded to the circuit insulating ceramic substrate 5, is of a spherical protruding form. The metal base portion 3 on the heat dissipating face 4a side of the reinforcement ceramic plate member 6 is called a heat dissipating face metal plate 4. A part such as a heat dissipating fin made of metal or a cooling jacket is attached by screwing or the like to the heat dissipating face 4a of the heat dissipating face metal plate 4 across a thermally conductive grease.

As shown in FIG. 1, external dimensions of the reinforcement ceramic plate member 6 are greater than external dimensions of the circuit insulating ceramic substrate 5. Also, as shown in FIG. 2, a thickness dimension Y1 of the circuit pattern metal plate 2 and a thickness dimension Y3 of a thickest portion of the heat dissipating face metal plate 4 are both smaller than a metal thickness dimension Y2 of the metal base portion 3 between the circuit insulating ceramic substrate 5 and the reinforcement ceramic plate member 6 (Y1<Y2, Y3<Y2).

Also, as shown in FIG. 1, the metal base portion 3 has a projecting portion residue 7 caused by a projecting portion 25 that supports the reinforcement ceramic plate member 6 in an interior of a casting mold 20 for manufacturing the metal-ceramic bonded substrate 1. Furthermore, the metal base portion 3 has a screw fastening hole (omitted from the drawing) for attaching the metal-ceramic bonded substrate 1 to a frame part, and a screw fastening hole 8 for attaching the metal-ceramic bonded substrate 1 to a heat dissipating fin or a cooling jacket, in a peripheral edge portion 3a of the metal base portion 3.

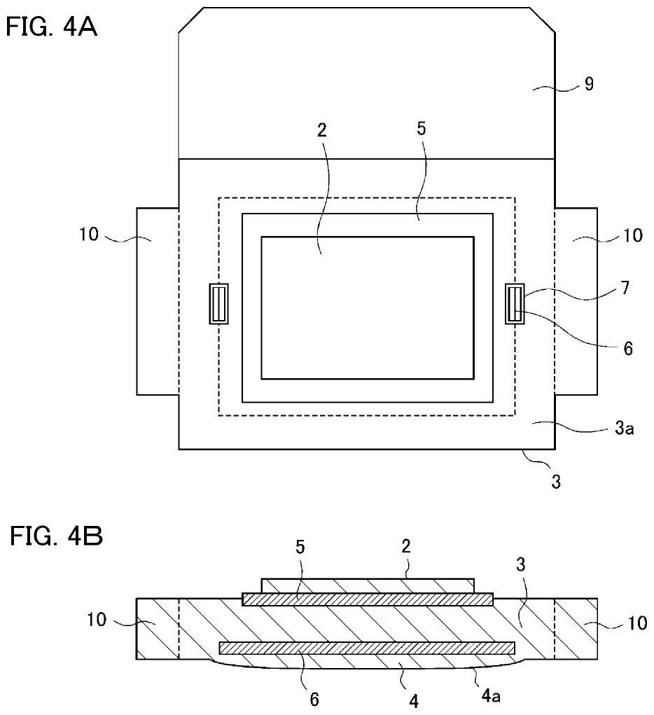

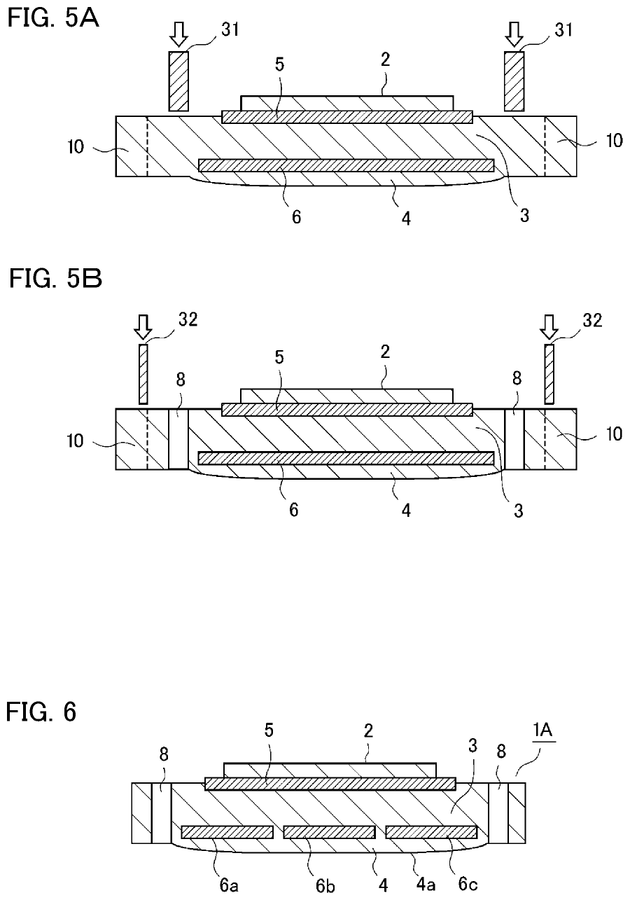

A method of manufacturing the metal-ceramic bonded substrate 1 according to the first embodiment will be described. FIGS. 4A and 4B, and FIGS. 5A and 5B are drawings showing a metal-ceramic bonded substrate manufacturing method according to the first embodiment, wherein FIGS. 4A and 4B are a plan view and a sectional view showing a metal-ceramic bonded substrate immediately after removal from a casting mold, and FIGS. 5A and 5B are sectional views showing a pressing process step.

Firstly, the casting mold 20 is prepared as a preparatory step. As shown in FIG. 3, the casting mold 20 is such that the circuit insulating ceramic substrate 5 and the reinforcement ceramic plate member 6 are set opposing in the interior, the casting mold 20 has an overflow portion 26 that is farther to an outer side in a horizontal direction than a metal base portion formation portion 23 that is a space for forming the metal base portion 3, that is, farther to the outer side than an external form of the metal-ceramic bonded substrate 1, and that communicates with the space, and a formation face 24a opposing the reinforcement ceramic plate member 6 is cut out into a spherical depressed form.

The casting mold 20 is configured of an upper mold 20A and a lower mold 20B. The metal base portion formation portion 23 of the casting mold 20 communicates with a circuit pattern metal plate formation portion 22 for forming the circuit pattern metal plate 2, a heat dissipating face metal plate formation portion 24 for forming the heat dissipating face metal plate 4, and the overflow portion 26.

The circuit pattern metal plate formation portion 22 is a space between the upper mold 20A and the circuit insulating ceramic substrate 5, and is formed by one portion of the circuit insulating ceramic substrate 5 being supported by and housed in the upper mold 20A. Also, the heat dissipating face metal plate formation portion 24 is a space between the lower mold 20B and the reinforcement ceramic plate member 6, and is formed by one portion of the reinforcement ceramic plate member 6 being supported by and housed in the projecting portion 25 of the upper mold 20A. Furthermore, the formation face 24a of the heat dissipating face metal plate formation portion 24 of the lower mold 20B is cut out into a spherical depressed form.

The casting mold 20 has a pouring inlet (omitted from the drawing) for pouring molten metal into the metal base portion formation portion 23, and a runner 21 extended between the metal base portion formation portion 23 and the circuit pattern metal plate formation portion 22 and between the metal base portion formation portion 23 and the heat dissipating face metal plate formation portion 24. Owing to the runner 21, the metal base portion formation portion 23 communicates with the circuit pattern metal plate formation portion 22 and the heat dissipating face metal plate formation portion 24, even when the circuit insulating ceramic substrate 5 and the reinforcement ceramic plate member 6 are housed in the interior of the casting mold 20.

A mold-release coating is applied to the interior of the casting mold 20 using painting, spraying, physical vapor disposition, or the like, with an object of preventing bonding with the molten metal. An oxide ceramic such as boron nitride, calcium oxide, or zirconium oxide, which has little reactivity with aluminum, is used as a mold-release coating material.

Continuing, the casting mold 20 in whose interior the circuit insulating ceramic substrate 5 and the reinforcement ceramic plate member 6 are set is moved into a bonding furnace. The bonding furnace is a nitrogen atmosphere, and with an oxygen concentration of 100 ppm or less, the casting mold 20 is heated to between 600° C. and 800° C., which is a pouring temperature, by controlling a heater temperature. Subsequently, molten metal weighed in advance and heated to the pouring temperature is pressurized using nitrogen gas, and poured into the interior of the casting mold 20 from the pouring inlet of the casting mold 20.

An aluminum alloy with aluminum as a main raw material, pure aluminum, or the like, which has high thermal conductivity, is used as the molten metal, which is a metal member configuring the circuit pattern metal plate 2, the metal base portion 3, and the heat dissipating face metal plate 4. Also, a ceramic material such as aluminum oxide or aluminum nitride, which is thermally and chemically stable even below a temperature in the region of 700° C., which is the melting point of an aluminum alloy or a pure aluminum-based material, is used as a ceramic material configuring the circuit insulating ceramic substrate 5 and the reinforcement ceramic plate member 6.

Subsequently, after the molten metal in the casting mold 20 is directionally solidified using a chiller, a substrate wherein the metal and the ceramic are bonded is removed from the casting mold 20, whereby the metal-ceramic bonded substrate shown in FIGS. 4A and 4B is obtained. The metal-ceramic bonded substrate immediately after removal from the casting mold 20 has a runner residue 9 and an overflow portion residue 10 farther to the outer side than the external form of the metal-ceramic bonded substrate 1 shown in FIG. 1, and has the projecting portion residue 7, which is a residue of the projecting portion 25 of the casting mold 20. As the runner residue 9 and the overflow portion residue 10 are unneeded portions, the runner residue 9 and the overflow portion residue 10 are cut off in the pressing process step shown in FIGS. 5A and 5B.

In the pressing process step, firstly, a screw fastening hole for attaching the metal-ceramic bonded substrate 1 to a frame part, and the screw fastening hole 8 for attaching the metal-ceramic bonded substrate 1 to a heat dissipating fin or a cooling jacket, are formed by pressing using a fastening hole press 31 in a peripheral edge portion of the metal base portion 3 of the metal-ceramic bonded substrate removed from the casting mold 20, as shown in FIG. 5A. Continuing, the runner residue 9 and the overflow portion residue 10 are cut off using an overflow portion residue press 32, as shown in FIG. 5B.

By so doing, the external form of the metal-ceramic bonded substrate 1 shown in FIG. 1 is formed. The metal-ceramic bonded substrate 1 completed by the heretofore described step is such that the heat dissipating face 4a is of a spherical protruding form owing to the formation face 24a of the lower mold 20B cut out into a spherical depressed form being transferred.

In the example shown in FIGS. 4A and 4B, the overflow portion residue 10 is provided symmetrically on two opposing sides of the metal-ceramic bonded substrate 1, but a position of the overflow portion 26 in the casting mold 20 is not limited to this. However, the overflow portion 26 is preferably provided so that the overflow portion residue 10 has linear symmetry with respect to a center of the metal-ceramic bonded substrate 1.

Also, although the reinforcement ceramic plate member 6 whose external dimensions are greater than those of the circuit insulating ceramic substrate 5 is used in the metal-ceramic bonded substrate 1 shown in FIG. 1 and FIG. 2, the configuration of the circuit insulating ceramic substrate 5 and the reinforcement ceramic plate member 6 is not limited to this. For example, a multiple of reinforcement ceramic plate members 6a, 6b, and 6c can also be used, as in the case of a metal-ceramic bonded substrate 1A shown in FIG. 6. Also, a multiple of reinforcement ceramic plate members may be further provided between the circuit insulating ceramic substrate 5 and the reinforcement ceramic plate member 6.

According to the method of manufacturing the metal-ceramic bonded substrate 1 according to the first embodiment, as heretofore described, the metal-ceramic bonded substrate 1 wherein the heat dissipating face 4a of the heat dissipating face metal plate 4 is formed by transfer in a spherical protruding form can easily be manufactured by using the casting mold 20 wherein the formation face 24a of the lower mold 20B is cut out into a spherical depressed form.

Also, by the overflow portion 26 communicating with the metal base portion formation portion 23 being provided farther to the outer side in the horizontal direction than the metal base portion formation portion 23 in the interior of the casting mold 20, that is, farther to the outer side than the external form of the metal-ceramic bonded substrate 1, the overflow portion residue 10 formed in the overflow portion 26 when causing molten metal to solidify and cool is restricted by the casting mold 20, because of which warping deformation due to thermal strain occurring because of a difference between linear expansion coefficients of the metal material and the ceramic material can be restricted. As the overflow portion residue 10 can be cut off in the pressing process step for forming the fastening hole 8, the external form of the metal-ceramic bonded substrate 1 can easily be formed, without increasing steps for cutting off the overflow portion residue 10.

Also, a casting defect such as a running defect in a molten metal flowing process or surface cracking in a solidification and cooling process can be restricted by the overflow portion 26 being provided neighboring a place in which a channel of the molten metal in the interior of the casting mold 20 is narrow. Furthermore, by a metal-ceramic bonded substrate removed from the casting mold 20 having the overflow portion residue 10, deformation of the external form of the metal-ceramic bonded substrate 1 when forming the fastening hole 8 in the subsequent pressing process step can be restricted.

Also, according to the metal-ceramic bonded substrate 1 according to the first embodiment, the heat dissipating face 4a is of a spherical protruding form, because of which, when a heat dissipating fin or a cooling jacket is attached to the heat dissipating face 4a across a thermally conductive grease, high heat dissipation can be secured because contact pressure with the thermally conductive grease is high, and contact is good. Furthermore, owing to the thickness dimension Y1 of the circuit pattern metal plate 2 and the thickness dimension Y3 of the thickest portion of the metal of the heat dissipating face metal plate 4 being set to be smaller than the metal thickness dimension Y2 of the metal base portion 3 between the circuit insulating ceramic substrate 5 and the reinforcement ceramic plate member 6, thermal strain of the circuit pattern metal plate 2 and the heat dissipating face metal plate 4 has little effect on the metal base portion 3, and warping deformation of the metal-ceramic bonded substrate 1 can be restricted. For these reasons, according to the first embodiment, the metal-ceramic bonded substrate 1 such that warping deformation is restricted, heat dissipation and external form accuracy are high, and furthermore, a casting defect such as a running defect is restricted, is obtained.

### Second Embodiment

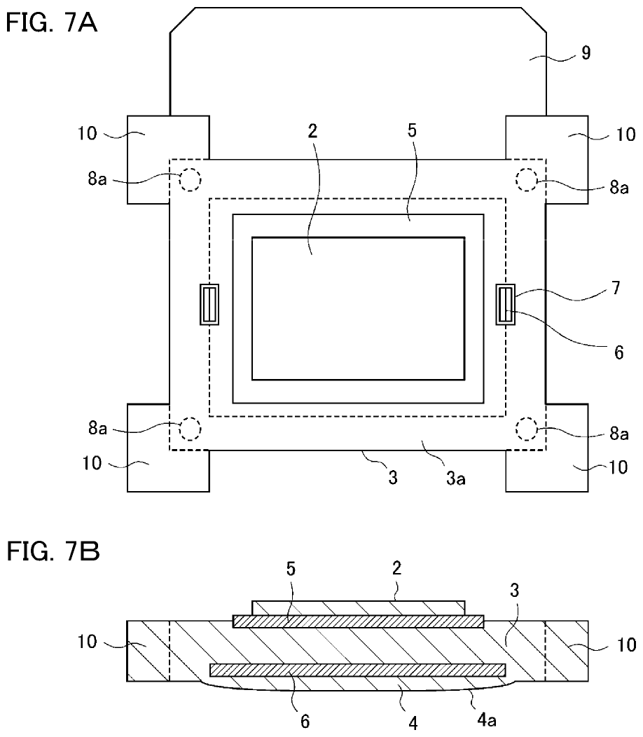

In a second embodiment of the invention, a modified example of the disposition of the overflow portion residue 10 in a metal-ceramic bonded substrate, that is, the disposition of the overflow portion 26 in the casting mold 20, will be described using FIGS. 7A and 7B to FIG. 10. As other configurations are the same as in the first embodiment, a description will be omitted here.

In the example shown in FIGS. 7A and 7B, the overflow portion residue 10 is disposed so as to neighbor a place 8a in which a fastening hole of the peripheral edge portion 3a of the metal base portion 3 is formed. By the overflow portion residue 10 being disposed in a vicinity of the place 8a in which a fastening hole is formed in this way, shearing deformation of the external form of the metal-ceramic bonded substrate 1, occurring when forming the fastening hole by the pressing process in a metal-ceramic bonded substrate removed from the casting mold 20, can be restricted. The fastening hole formed neighboring the overflow portion residue 10 may be any screw fastening hole for attaching a metal-ceramic bonded substrate to a frame part, a heat dissipating fin, or a cooling jacket.

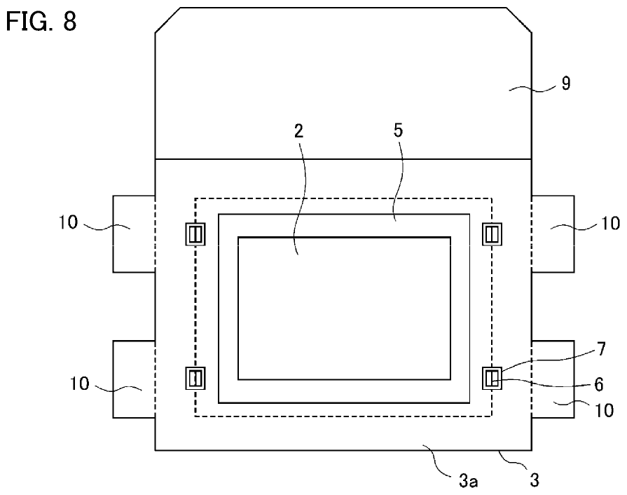

Also, in the example shown in FIG. 8, the metal base portion 3 has four projecting portion residues 7, and the overflow portion residue 10 is disposed so as to neighbor the projecting portion residues 7. The channel of the molten metal in the interior of the casting mold 20 is narrow in a place in which the projecting portion 25 is provided, and a casting defect, such as a running defect in the molten metal flowing process of pouring molten metal into the casting mold 20 or surface cracking in the solidification and cooling process, is likely to occur. Because of this, the channel of the molten metal can be widened by the overflow portion 26 being provided neighboring a place in which the projecting portion 25 of the casting mold 20 is provided, and a casting defect such as a running defect or surface cracking can be restricted.

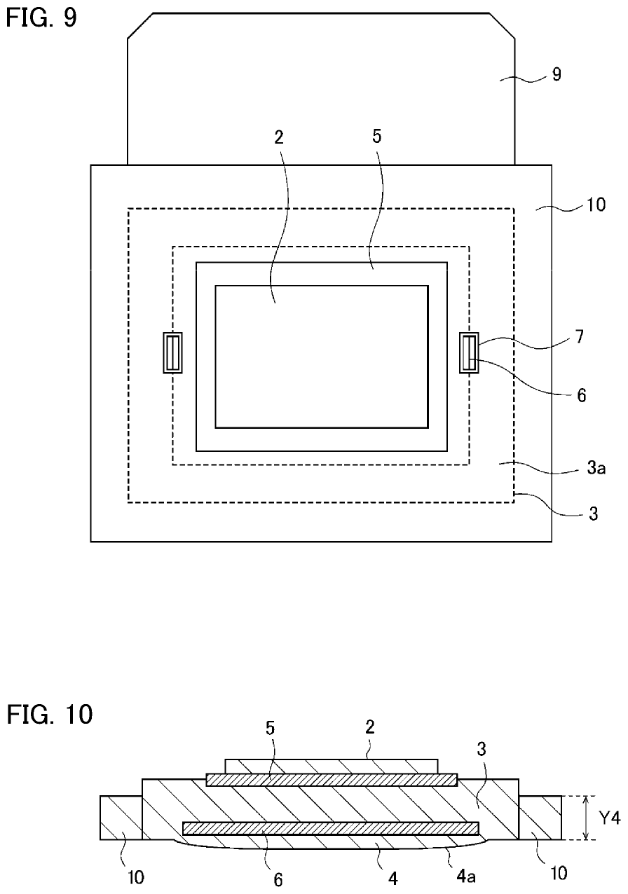

Also, in the example shown in FIG. 9, the overflow portion residue 10 is disposed so as to neighbor the whole of the peripheral edge portion 3a of the metal base portion 3. A casting defect such as a running defect in the molten metal flowing process, a defect such as cold shut or a ripple mark occurring due to the flow of molten metal dividing and converging, or surface cracking in the solidification and cooling process, is likely to occur in the peripheral edge portion 3a of the metal base portion 3. Because of this, the overflow portion 26 is provided neighboring the whole of an outer periphery of the metal base portion formation portion 23 of the casting mold 20, whereby division and convergence of the flow of molten metal can be restricted, and a casting defect such as a running defect, cold shut, a ripple mark, or surface cracking can be restricted.

Also, after the pressing process step, an adhesive is applied to an outer peripheral face on the circuit pattern metal plate 2 side of the metal-ceramic bonded substrate 1, and a frame part is affixed. At this time, when sag due to the pressing process has occurred on the outer peripheral face on the circuit pattern metal plate 2 side, the adhesive flows to a side face of the metal-ceramic bonded substrate 1, causing a defect. Because of this, care is needed to ensure that sag does not occur on the outer peripheral face on the circuit pattern metal plate 2 side in the pressing process step.

Therefore, by a thickness dimension Y4 of the overflow portion residue 10 being smaller than the thickness dimension of the metal base portion 3, and one face of the overflow portion residue 10 and the heat dissipating face 4a of the heat dissipating face metal plate 4 of the metal base portion 3 being coplanar, as shown in FIG. 10, sag does not occur on the outer peripheral face on the circuit pattern metal plate 2 side when cutting off the overflow portion residue 10 in the pressing process step.

In the same way as in the first embodiment, the examples of the disposition of the overflow portion residue 10 shown in FIGS. 7A and 7B to FIG. 10 are also such that by the overflow portion 26 being provided in the interior of the casting mold 20, the overflow portion residue 10 formed in the overflow portion 26 when causing molten metal to solidify and cool is restricted by the casting mold 20, because of which warping deformation due to thermal strain occurring because of the difference between the linear expansion coefficients of the metal material and the ceramic material can be restricted.

According to the second embodiment, in addition to the same advantages as the first embodiment, shearing deformation of the external form of the metal-ceramic bonded substrate 1 caused by the pressing process can be restricted, and a casting defect such as a running defect, cold shut, a ripple mark, or surface cracking can be restricted, by the disposition of the overflow portion 26 of the casting mold 20, whereby quality of the metal-ceramic bonded substrate 1 increases. The embodiments can be freely combined, and each embodiment can be modified or abbreviated as appropriate, without departing from the scope of the invention.

### REFERENCE SIGNS LIST

1, 1A metal-ceramic bonded substrate, 2 circuit pattern metal plate, 3 metal base portion, 3a peripheral edge portion, 4 heat dissipating face metal plate, 4a heat dissipating face, 5 circuit insulating ceramic substrate, 6, 6a, 6b, 6c reinforcement ceramic plate member, 7 projecting portion residue, 8 fastening hole, 8a place in which fastening hole is formed, 9 runner residue, 10 overflow portion residue, 20 casting mold, 20A upper mold, 20B lower mold, 21 runner, 22 circuit pattern metal plate formation portion, 23 metal base portion formation portion, 24 heat dissipating face metal plate formation portion, 25 projecting portion, 26 overflow portion, 31 fastening hole press, 32 overflow portion residue press

1. A metal-ceramic bonded substrate, comprising:
a circuit insulating ceramic substrate such that a circuit pattern metal plate is bonded to one face and a metal base portion is bonded to another face; and
a reinforcement ceramic plate member disposed opposing the circuit insulating ceramic substrate in an interior of the metal base portion, wherein
the metal base portion is such that a heat dissipating face, which is a face on a side opposite to that of a face bonded to the circuit insulating ceramic substrate, is of a spherical protruding form.

2. The metal-ceramic bonded substrate according to claim 1, wherein an external dimension of the reinforcement ceramic plate member is greater than that of the circuit insulating ceramic substrate.

3. The metal-ceramic bonded substrate according to claim 1, wherein a thickness dimension of a thickest portion of metal between the reinforcement ceramic plate member and the heat dissipating face in the metal base portion is smaller than a thickness dimension of metal between the circuit insulating ceramic substrate and the reinforcement ceramic plate member.

4.-10. (canceled)

11. The metal-ceramic bonded substrate according to claim 2, wherein a thickness dimension of a thickest portion of metal between the reinforcement ceramic plate member and the heat dissipating face in the metal base portion is smaller than a thickness dimension of metal between the circuit insulating ceramic substrate and the reinforcement ceramic plate member.

12. The metal-ceramic bonded substrate according to claim 1, wherein a thickness dimension of the circuit pattern metal plate is smaller than a metal thickness dimension of the metal base portion between the circuit insulating ceramic substrate and the reinforcement ceramic plate member.

13. The metal-ceramic bonded substrate according to claim 2, wherein a thickness dimension of the circuit pattern metal plate is smaller than a metal thickness dimension of the metal base portion between the circuit insulating ceramic substrate and the reinforcement ceramic plate member.

14. The metal-ceramic bonded substrate according to claim 3, wherein a thickness dimension of the circuit pattern metal plate is smaller than a metal thickness dimension of the metal base portion between the circuit insulating ceramic substrate and the reinforcement ceramic plate member.

15. A metal-ceramic bonded substrate manufacturing method, which is a method of manufacturing a metal-ceramic bonded substrate including a circuit insulating ceramic substrate such that a circuit pattern metal plate is bonded to one face and a metal base portion is bonded to another face, and a reinforcement ceramic plate member disposed opposing the circuit insulating ceramic substrate in an interior of the metal base portion, wherein a heat dissipating face, which is a face of the metal base portion on a side opposite to that of a face bonded to the circuit insulating ceramic substrate, is of a spherical protruding form, wherein
a casting mold such that the circuit insulating ceramic substrate and the reinforcement ceramic plate member are set opposing in an interior, the casting mold has an overflow portion communicating with a space for forming the metal base portion farther to an outer side than the space in a horizontal direction, and a face opposing the reinforcement ceramic plate member is cut out into a spherical depressed form, is prepared,
molten metal heated to a predetermined temperature is poured into the interior of the casting mold, the molten metal is caused to harden by cooling the casting mold, and the metal-ceramic bonded substrate is removed from the casting mold, after which an overflow portion residue formed integrally with the metal base portion is cut off.

16. The metal-ceramic bonded substrate manufacturing method according to claim 15, wherein a screw fastening hole for attaching the metal-ceramic bonded substrate to a frame part, a heat dissipating fin, or a cooling jacket is formed by a pressing process in a peripheral edge portion of the metal base portion of the metal-ceramic bonded substrate removed from the casting mold, after which the overflow portion residue is cut off by a pressing process.

17. The metal-ceramic bonded substrate manufacturing method according to claim 16, wherein the overflow portion residue is formed so as to neighbor a place in which the fastening hole of the peripheral edge portion of the metal base portion is formed.

18. The metal-ceramic bonded substrate manufacturing method according to claim 16, wherein the casting mold has a projecting portion for supporting the reinforcement ceramic plate member in the interior, and the overflow portion residue is formed so as to neighbor a residue of the projecting portion in the metal base portion.

19. The metal-ceramic bonded substrate manufacturing method according to claim 16, wherein the overflow portion residue is formed so as to neighbor a whole of the peripheral edge portion of the metal base portion.

20. The metal-ceramic bonded substrate manufacturing method according to claim 15, wherein a thickness dimension of the overflow portion residue is smaller than a thickness dimension of the metal base portion, and one face of the overflow portion residue and the heat dissipating face of the metal base portion are coplanar.

21. The metal-ceramic bonded substrate manufacturing method according to claim 16, wherein a thickness dimension of the overflow portion residue is smaller than a thickness dimension of the metal base portion, and one face of the overflow portion residue and the heat dissipating face of the metal base portion are coplanar.
